(19) United States
(12) Patent Application Publication
(10) Pub. No.: US 2012/0077312 A1
(43) Pub. Date: Mar. 29, 2012

(54) FLIP-CHIP BONDING METHOD TO REDUCE VOIDS IN UNDERFILL MATERIAL

(76) Inventors: Kuo-Yuan LEE, Kaohsiung (TW); Yung-Hsiang Chen, Kaohsiung (TW); Wen-Chun Chiu, Kaohsiung (TW); Kao-Hsiung Lin, Kaohsiung (TW)

(21) Appl. No.: 13/050,538

(22) Filed: Mar. 17, 2011

(30) Foreign Application Priority Data
Sep. 23, 2010 (TW) 099132239

(51) Int. Cl. H01L 21/56

(52) U.S. Cl. 438/108; 257/E21.503

(57) ABSTRACT

Disclosed is a flip-chip bonding method to reduce voids in underfill material. A substrate with connecting pads is provided. At least a chip with a plurality of bumps is bonded on the substrate and then an underfill material is formed between the chip and the substrate. Finally, the substrate is placed in a pressure oven in which a positive pressure greater than one atm is provided, meanwhile, the underfill material is thermally cured with exerted pressures to reduce bubbles or voids trapped inside the underfill material to avoid popcorn issues due to CTE mismatch between the chip and the substrate. In one embodiment, another underfill material is further formed between a plurality of chips and bubbles or voids trapped between the chips are also reduced by the pressurized curing.

### FIELD OF THE INVENTION

The present invention relates to packaging technology of semiconductor devices, and more specifically to a flip-chip bonding method to reduce voids in underfill material.

### BACKGROUND OF THE INVENTION

Flip-chip packaging technology is an advanced packaging technology to electrically connect a chip to a substrate with the advantages of smaller footprint and shorter electrical paths. In order to fully attach a chip to a substrate, an underfill material with fluidity is widely used to fill into the gap between the chip and the substrate to compensate CTE mismatch, to completely adhere the chip to the substrate, and to protect the electrical connections between the chip and the substrate from the influence of environment such as stresses, moisture, particles, and others.

However, under the developing trend of high density and miniature, the gap between a chip and a substrate becomes smaller and smaller with more and more connecting terminals such as bumps disposed in the gap. Especially, when multiple chips are stacked, the gaps between the chips are even smaller and far away from the substrate where underfill material can not easily fill into the gaps so that voids or bubbles are easily formed and trapped inside the underfill material. Due to CTE mismatch between a chip and a substrate during thermal cycling processes, popcorn defects are easily occurred leading to reliability issues.

When vertically stacking a plurality of chips in a 3D structure, once there are many trapped bubbles inside the underfill material, the encapsulation and the adhesion of the underfill material are greatly be reduced causing poor adhesion between stacked chips leading to reliability issues of the 3D IC package. Furthermore, after curing underfill material, IC temperature risen due to operation rapidly expands the bubbles trapped inside the underfill material causing popcorn leading to delamination, crack and potential damage of 3D IC package.

### SUMMARY OF THE INVENTION

The main purpose of the present invention is to provide a flip-chip bonding method to reduce voids in underfill material to reduce the bubbles trapped inside underfill material to avoid poor adhesion between chips and substrates due to CTE mismatch.

The second purpose of the present invention is to provide a flip-chip bonding method to reduce voids in underfill material when vertically stacking a plurality of chips to reduce voids between stacked chips and to avoid poor adhesions and popcorn issues between stacked chips.

According to the present invention, a flip-chip bonding method to reduce voids in underfill material is revealed. Firstly, a substrate is provided where the substrate has a plurality of connecting pads. Then, the first chip is bonded on the substrate where a plurality of first bumps of the first chip are bonded to the connecting pads of the substrate and a first underfill material is formed between the first chip and the substrate to encapsulate the first bumps. Finally, the first underfill material is thermally cured with exerted pressures during placing the substrate in a pressure oven to provide a positive pressure greater than one atm (atmospheric pressure) exerted on the first underfill material to reduce the bubbles trapped inside the first underfill material.

The flip-chip bonding method to reduce voids in underfill material according to the present invention has the following advantages and effects:
1. Through a specific processing sequence of thermally curing underfill material with exerted pressures as a technical mean, the substrate is placed inside a pressure oven with a positive pressure greater than one atm exerted on the substrate to reduce the bubbles trapped inside underfill material and to avoid poor adhesion between chips and substrates due to CTE mismatch.
2. Through a specific processing sequence of thermally curing underfill material with exerted pressures as a technical mean, when vertically stacking a plurality of chips, the underfill material can be thermally cured with exerted pressures to reduce the bubbles trapped inside the underfill material to avoid poor adhesion between stacked chips and popcorn issues.

### DESCRIPTION OF THE DRAWINGS

FIGS. 1A to 1E are cross-sectional views of elements illustrating a flip-chip bonding method to reduce voids in underfill material according to the first embodiment of the present invention.

FIGS. 2A and 2B are cross-sectional views of elements illustrating the step of disposing the first chip during the flip-chip bonding method according to a variation of the first embodiment of the present invention.

FIGS. 3A to 3F are cross-sectional views of elements illustrating another flip-chip bonding method to reduce voids in underfill material according to the second embodiment of the present invention.

### DETAILED DESCRIPTION OF THE INVENTION

With reference to the attached drawings, the present invention is described by means of the embodiment(s) below where the attached drawings are simplified for illustration purposes only to illustrate the structures or methods of the present invention by describing the relationships between the components and assembly in the present invention. Therefore, the components shown in the figures are not expressed with the actual numbers, actual shapes, actual dimensions, nor with the actual ratio. Some of the dimensions or dimension ratios have been enlarged or simplified to provide a better illustration. The actual numbers, actual shapes, or actual dimension ratios can be selectively designed and disposed and the detail component layouts may be more complicated.

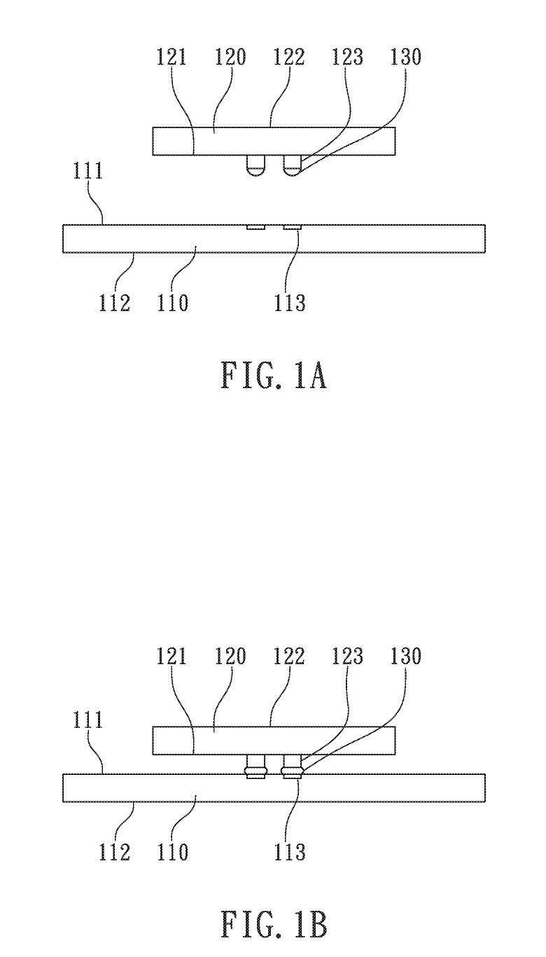

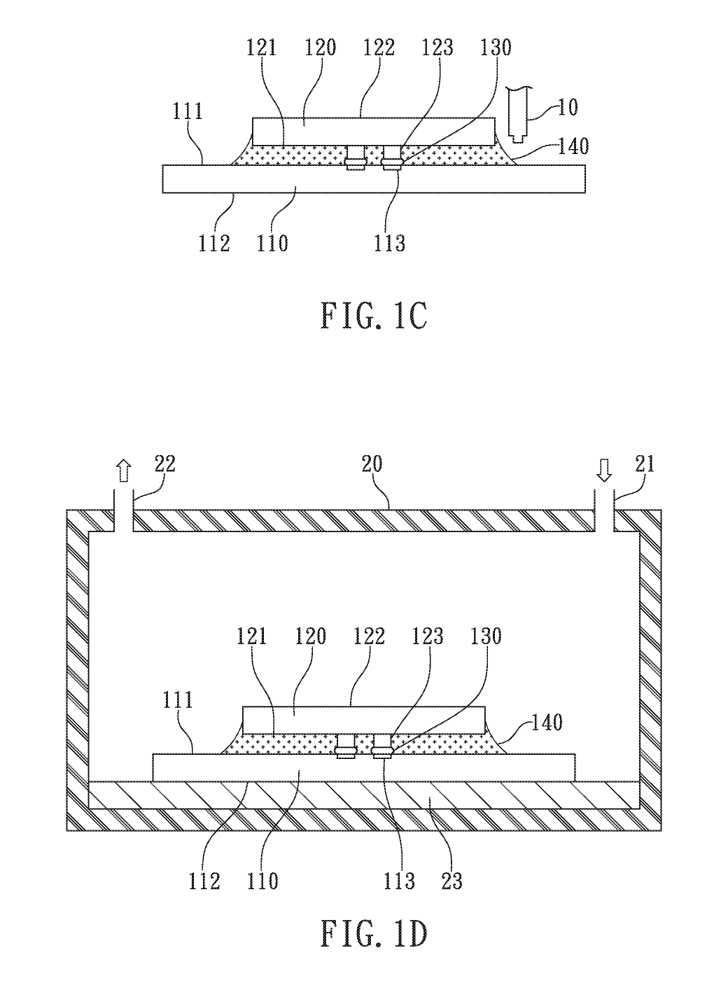

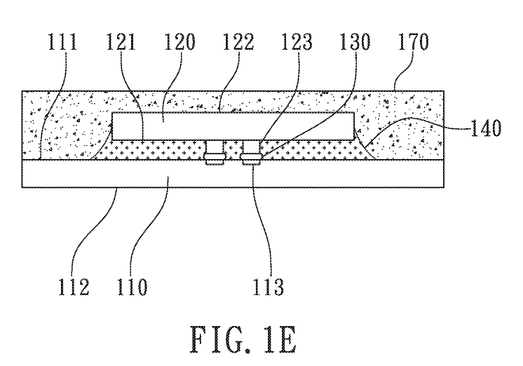

According to the first embodiment of the present invention, a flip-chip bonding method to reduce voids in underfill material is illustrated from FIG. 1A to FIG. 1E for cross-sectional views of each processing step.

Firstly, as shown in FIG. 1A, a substrate 110 is provided. The substrate 110 has a top surface 111, a bottom surface 112, and a plurality of connecting pads 113 disposed on the top surface 111. The substrate 110 is a chip carrier for flip-chip packages which can be a single flip-chip package unit with a specific dimension or a substrate strip with many flip-chip packaging units which can be singulated into individual flip-chip packages at the back-end singulation process. Usually the substrate 110 is a printed circuit board with a single layer or doubt layers of circuitry. When the substrate 110 is a multi-layer board, the substrate 110 further has a plurality of plated through holes (PTH) not shown in the figure. The substrate 110 can also be chosen from a flexible wiring film, a leadless leadframe with a back tape, a ceramic substrate, a leadframe, or a metal carrying panel. Alternatively, the substrate 110 can be a mother chip with a larger chip dimension. Furthermore, the top surface 111 of the substrate 110 is designed for attaching chips and the bottom surface 112 for disposing a plurality of solder balls (not shown in the figure) or external components to provide external surface interconnection. The connecting pads 113 can be conductive metals chosen from Aluminum, Copper, Aluminum alloy, or Copper alloy as the input/output contact points of substrate circuitry for connecting chip(s).

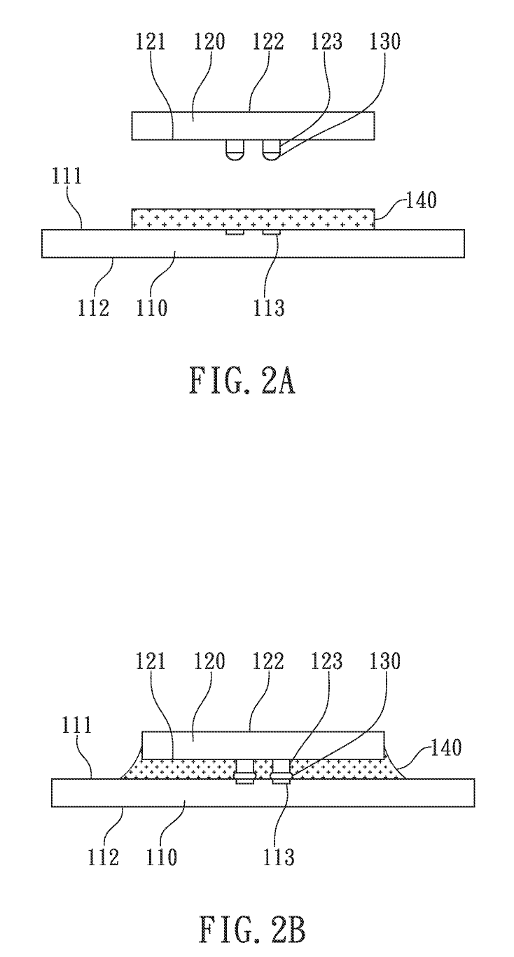

Then, as shown in FIG. 1B, the first chip 120 is bonded on the top surface 111 of the substrate 110 by known flip-chip bonding technologies. The first chip 120 has a first active surface 111, a first back surface 112 opposing to the first active surface 111, and a plurality of first bumps 123 disposed on the first active surface 111. After the flip-chip bonding, the first bumps 123 are bonded to the connecting pads 113 as shown in FIG. 1C where a first underfill material 140 is formed between the first chip 120 and the substrate 110 to encapsulate the first bumps 123. To be more specific, as shown in FIGS. 1A and 1B again, the first active surface 121 is the surface of the first chip 120 that has IC active devices fabricated on it. The locations of the connecting pads 113 of the substrate 110 are corresponding to the locations of the first bumps 123 of the first chip 120 where the first chip 120 is flip-chip bonded with heat and pressures to the connecting pads 113 on the top surface 111 of the substrate 110 with the first active surface 121 facing to the substrate 110 so that the first bumps 123 of the first chip 120 are electrically and mechanically connected to the connecting pads 113 of the substrate 110. In the present embodiment, the first bumps 123 are located at the central region of the first active surface 121 in linear arrangement where the material of the first bumps 113 are non-reflow bumps such as gold bumps, copper bumps, aluminum bumps, or conductive polymer bumps and the shapes of the first bumps can be square, cylindrical, pillar, hemisphere, or sphere. In other embodiments, the first bumps 123 can be solder bumps or stud bumps. Preferably, the first bumps 123 are pillar bumps such as copper pillar bumps which can resist high temperature without deformation or melting and to keep constant fine pitches between the first bumps 123 without bump collapse or deformation during flip-chip bonding processes, moreover, copper pillar bumps can be formed by electroplating with a lower cost. Preferably, as shown in FIG. 1A again, each first bump 123 has a solder cap 130 such as tin-lead solder or lead-free solder (Tin-96.5%, Silver-3%, Copper-0.5%) where the solder cap 130 can be disposed on the protrusive end surface of the first bump 123 by printing, electroplating, transfer printing to establish and enhance the electrical and mechanical connections between the first bumps 123 and the connecting pads 113 of the substrate 110 by melting the solder caps 130 during reflow processes as shown in FIG. 2. Moreover, the pitches between the pillar bumps during flip-chip bonding can be much smaller than the conventional solder bumps without electrical short between the pillar bumps.

As shown in FIG. 1C, after the first chip 120 is bonded on the top surface 111 of the substrate 110, the first underfill material 140 is filled into the gap between the substrate 110 and the first chip 120 by dispensing. To be described in more detail, the first underfill material 140 is dielectric and fluid before curing. The first underfill material 140 is disposed by a dispensing needle using capillary forces to fill into the gap between the top surface 111 of the substrate 110 and the first active surface 121 of the first chip 120 to protect the exposed portions of the first bumps 123. The first underfill material 140 should be cured so that the thermal stresses caused by temperature variation between the substrate 110 and the first chip 120 can not concentrated on a certain bump or on a certain region of the first chip 120 to prevent leakage between the first bumps 123 due to impurity and to avoid any damages caused by external contaminations from the environment. In the present embodiment, the bubbles or voids trapped in the first underfill material 140 may specially concentrate between the first bumps 123 which are very difficult to remove by conventional methods.

Then, the substrate 110 and the first chip 120 are placed inside a pressure oven 20, meanwhile, the underfill material 140 is thermally cured with exerted pressures where the pressure oven 20 provides a positive pressure greater than one atm to the first underfill material 140 to reduce bubbles or voids trapped inside the first underfill material 140 so that there is no voids between the first active surface 121 of the first chip 120 and the substrate 110 to enhance the reliability and quality of the products and to avoid popcorn between the first chip 120 and the substrate 110 due to CTE mismatch during thermal cycles. To be more specific, when the underfill material 140 is thermally cured with exerted pressures, the positive pressure of the pressure oven 20 ranges from 1.8 atm to 8 atm and the heating temperature ranges from 100° C. to 160° C. with continuous exhausting. To be described in detail, the temperature of the pressure oven 20 can be pre-set at the curing temperature with a pre-set pressure where the pressure oven 20 has a gas entrance 21 and an exhaust 22. The substrate 110 placed on the stage 23 inside the pressure oven 20 is experienced heating and pressuring at the same time. When the temperature of the pressure oven 20 continues to rise and reach Tg temperature of the underfill material 140, the underfill material 140 become more fluid. By blowing more gases into the pressure oven 20 through the gas entrance 21, the positive pressure inside the pressure oven 20 still keeps between 1.8 atm and 8 atm with the exhaust 22 open, i.e., the gas pressure at the gas entrance 21 ranges from 1 to 7 Kg/cm² to make the high-temperature gas inside the pressure oven 20 become high-pressure fluid when the underfill material 140 is cured and to force the bubbles or the solvent inside the underfill material 140 to evaporate inside the pressure oven 20 and to be vented from the exhaust 22 to keep good atmosphere inside the pressure oven 20. Moreover, the gas flow rate flowing out of the exhaust 22 should be smaller than the gas flow rate flowing into the gas entrance 21 to keep a positive pressure inside the pressure oven 20 to continuously force or shrink the bubbles trapped inside the underfill material 140, in the mean time, the underfill material 140 is cured under the above-described heating conditions. Finally, as shown in FIG. 1E, a molding process is performed where a molding compound 170 is disposed on the top surface 111 of the substrate 110 to encapsulate the first chip 120.

In the present invention, the material and the formation of the first underfill material 140 are not limited. In a various embodiment, as shown in FIG. 2A, before bonding the first chip 120, the first underfill material 140 is pre-disposed on the substrate 110 by stencil printing or attaching the first underfill material 140 on the die-attaching area of the substrate 110. The first underfill material 140 can be epoxy, anisotropic conductive film (ACF), non-conductive film (NCF), ACP, or NCP. As shown in FIG. 2B, during bonding the first chip 120 on the substrate 110, the first bumps 123 penetrate through the first underfill material 140 and bond to the connecting pads 113 to electrically connect the first chip 120 to the substrate 110. In one various embodiment, the first underfill material 140 are non-fluid or low-fluid underfill material where the bubbles or voids trapped inside the first underfill material 140 may concentrate at the first active surface 121 of the first chip 120, so that the adhering interface of the first underfill material 140 against the top surface 111 of the substrate 110 are not fragmented and the solder caps 130 will not easily crack. By implementing the process of thermally curing the underfill material 140 with exerted pressures, the bubbles or voids trapped inside the first underfill material can be removed or shrunk.

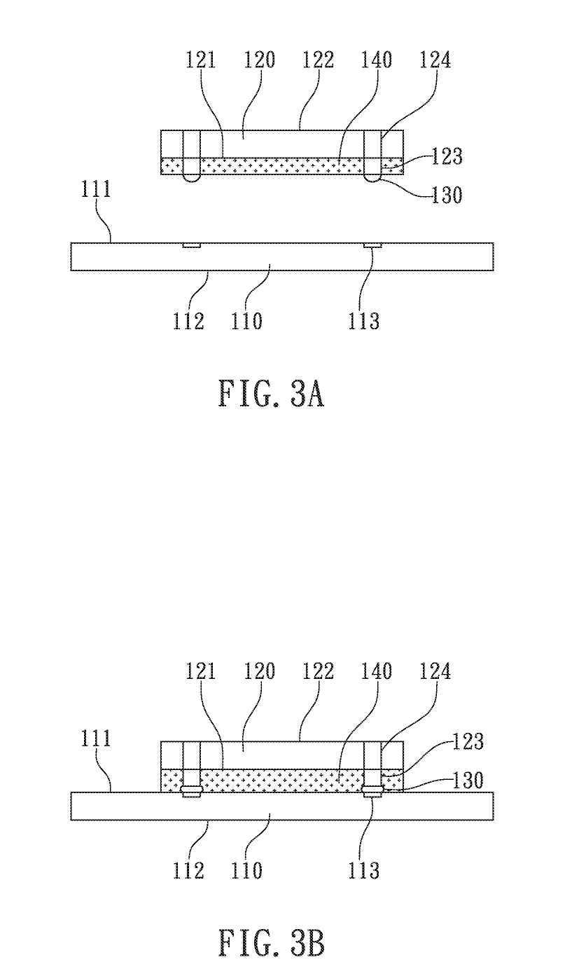

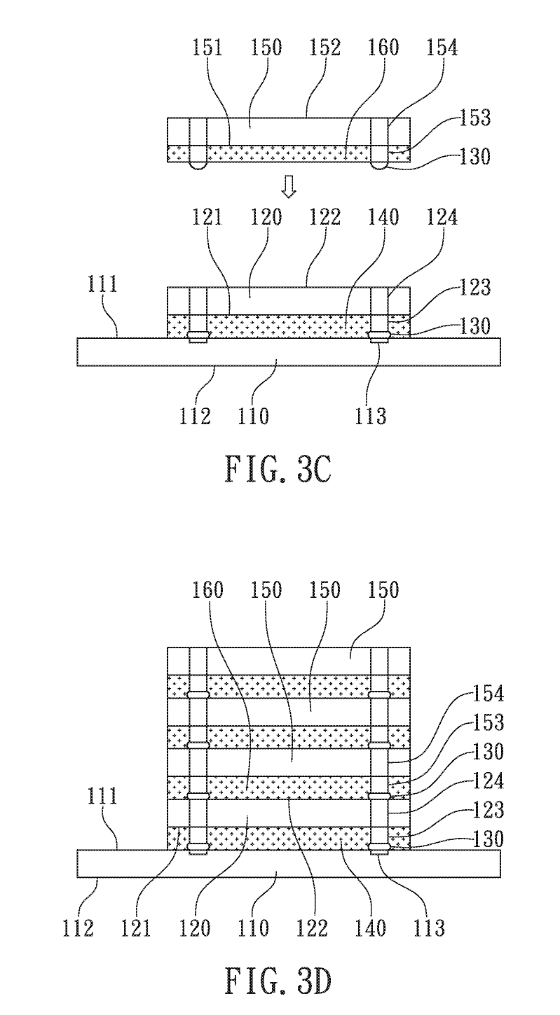

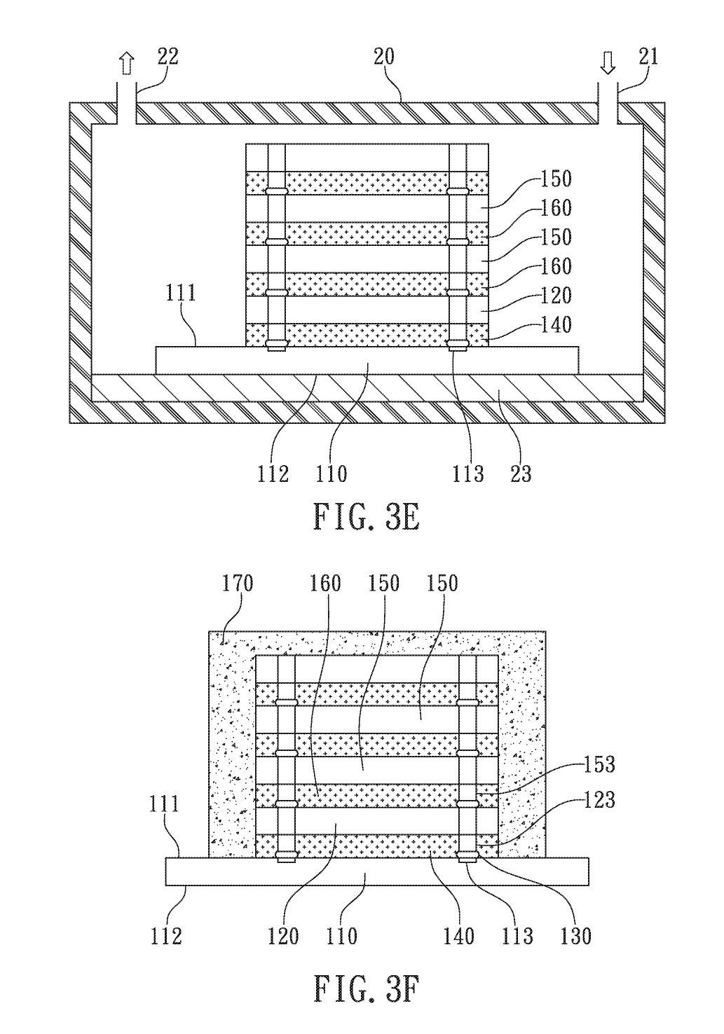

Another flip-chip bonding method to reduce voids in underfill material is revealed according to the second embodiment of the present invention which is illustrated from FIG. 3A to FIG. 3F for cross-sectional views of each processing step to be implemented in vertically stacking multi-chip packages where the main packaging process flow is the same as the one of the first embodiment which will not be described in detail again. The major components with the same nomenclature and assigned numbers are the same as the first embodiment which will be followed here.

In the present embodiment, the chips described in the flip-chip bonding method are not limited to bumps disposed at the center of the chips which can also be bumps disposed on one single side, two opposing sides, or peripheries where the corresponding substrate design is changed accordingly. As shown in FIG. 3A, in the present embodiment, the first bumps 123 of the first chip 120 are located at peripheries of the first active surface 121, for example, at two sides of the first active surface 121. In other various embodiment, the first bumps 123 can locate at one single side of the first active surface 121.

As shown in FIG. 3A again, before disposing the first chip 120, the first underfill material 140 fully encapsulates the first active surface 121 of the first chip 120 in wafer form with the first bumps 123 exposed from the first underfill material 140, i.e., a plurality of protruding surfaces of the pillar-type first bumps 123 are exposed from the first underfill material 140 where solder caps 130 are disposed on the protruding surfaces of the first bumps 123 and are also exposed from the first underfill material 140 for external interconnection. The first underfill material 140 can be disposed on the first active surface 121 of the first chip 120 by printing or by dispensing. During bonding the first chip 120, the first underfill material 140 is attached to the top surface 111 of the substrate 110 followed by a reflow process. As shown in FIG. 3B, the solder caps 130 on the first bumps 123 melt and join to the connecting pads 113 of the substrate 110. In the present embodiment, the bubbles or voids trapped inside the first underfill material 140 may specially concentrate on the top surface 111 of the substrate 110.

Furthermore, as shown in FIG. 3A and FIG. 3B again, the first chip 120 further as a plurality of first TSVs (Through Silicon Vias) 124 which are through holes through the chip with high aspect ratios fabricated inside the first chip 120 filled with conductive material in the through holes to form TSV to provide electrical connections in the vertical direction. Moreover, as shown in FIG. 3C and FIG. 3D, the method further comprises a process of disposing at least a second chip 150 on top of the first chip 120 after disposing the first chip 120 and before thermally curing the underfill material 140 with exerted pressures. To be more specific, the second chip 150 has a second active surface 151, a second back surface 152, and a plurality of second bumps 153. After disposing the second chip 150, the second bumps 153 are electrically connected to the first TSVs 124 where a second underfill material 160 is formed between the second chip 150 and the first chip 120 to encapsulate the second bumps 153. To be described in more detail, the second chip 150 and the first chip 120 can be the chips with the same dimensions and the same functions and the same material which can be the chips picked from the same wafer where the second underfill material 160 can be disposed to fully encapsulate the second active surface 151 of the second chip 150 in wafer form with the second bumps 153 exposed from the second underfill material 160. Solder caps 130 are also disposed on top of the second bumps 153 where the second chip 150 further has a plurality of second TSVs 154. The second chip 150 stacked on top is electrically connected to the first chip 120 by flip-chip bonding the second bumps 153 to the first TSVs 124.

Preferably, as shown in FIG. 3D, the first TSVs 124 penetrate from the first active surface 121 to the first back surface 122 where the second TSVs 154 penetrate from the second active surface 151 to the second back surface 152 where RDL can be eliminated. The second chip 150 is vertically stacked on top of the first chip 120. An upper second chip 150 also can be vertically stacked on a lower second chip 150. By repeating the process of disposing the second chip 150, a plurality of second chips 150 can be vertically stacked on each another and connected to the first chip 120 to achieve increasing of memory capability or more functions.

Then, as shown in FIG. 3E, the substrate 110 with the vertically stacked chips 120 and 150 is placed in a pressure oven 20, meanwhile, the first underfill material 140 is thermally cured with exerted pressures in the pressure oven 20 to provide a positive pressure greater than one atm exerted on the first underfill material 140 to reduce the bubbles trapped inside the first underfill material 140. During thermally curing the first underfill material 140 with exerted pressures, the second underfill material 160 is also cured to make the second underfill material 160 more solid and to eliminate one step of thermally curing the second underfill material 160 to reduce the bubbles trapped inside the first underfill material 140 and the second underfill material 160 to avoid poor adhesion between stacked chips and popcorn.

Finally, as shown in FIG. 3F, a molding process is performed where a molding compound 170 is disposed on the top surface 111 of the substrate 110 to encapsulate the first chip 120 and the second chip 150 where the molding compound 170 is an epoxy molding compound (EMC) which can be formed by transfer molding or by compression molding to cure the EMC to protect stacked chips from external stresses, moisture, or damages and corrosions from other external material.

The above description of embodiments of this invention is intended to be illustrative but not limited. Other embodiments of this invention will be obvious to those skilled in the art in view of the above disclosure which still will be covered by and within the scope of the present invention even with any modifications, equivalent variations, and adaptations.

What is claimed is:

1. A flip-chip bonding method to reduce voids in underfill material comprising:
providing a substrate having a plurality of connecting pads on a top surface of the substrate;
bonding a first chip on the substrate, wherein the first chip has a plurality of first bumps connecting to the connecting pads and a first underfill material is formed between the first chip and the substrate so that the first bumps are encapsulated;
placing the first chip and the substrate inside a pressure oven, meanwhile, thermally curing the first underfill material with exerted pressures in the pressure oven to provide a positive pressure greater than one atm exerted to the first underfill material to reduce voids or bubbles trapped inside the first underfill material.

2. The flip-chip bonding method as claimed in claim 1, wherein the pressure of the pressure oven is maintained between 1.8 atm to 8.0 atm during the thermally curing of the underfill material.

3. The flip-chip bonding method as claimed in claim 1, wherein the first underfill material fully encapsulates a first active surface of the first chip in wafer form with a plurality of protruding surfaces of the first bumps exposed from the first underfill material before the first chip is bonded.

4. The flip-chip bonding method as claimed in claim 3, wherein the first chip further has a plurality of first through silicon holes connecting the bumps and after bonding the first chip the method further comprises the step of disposing at least a second chip on the first chip, wherein the second chip has a plurality of second bumps electrically connected to the first through silicon holes, and a second underfill material is formed between the second chip and the first chip so that the second bumps are encapsulated.

5. The flip-chip bonding stacking method as claimed in claim 4, wherein the second chip and the first chip are identical chips where the second underfill material is also disposed in wafer form.

6. The flip-chip bonding stacking method as claimed in claim 5, wherein the second underfill material is also thermally cured with exerted pressures in the pressure oven during the process of thermally curing the first underfill material.

7. The flip-chip bonding method as claimed in claim 6, further comprising performing a molding step to form a molding compound on the substrate to encapsulate the first chip and the second chip after thermally curing the first underfill material with exerted pressures.

8. The flip-chip bonding method as claimed in claim 1, further comprising performing a molding step to form a molding compound on the substrate to encapsulate the first chip after thermally curing the first underfill material with exerted pressures.

9. The flip-chip bonding method as claimed in claim 1, wherein the first underfill material is disposed into the gap between the first chip and the substrate by dispensing after the first chip is bonded.

10. The flip-chip bonding method as claimed in claim 1, wherein the first underfill material is pre-disposed on the substrate before the first chip is bonded, and wherein the first bumps penetrate through the first underfill material and bond to the connecting pads during bonding the first chip.

11. The flip-chip bonding method as claimed in claim 1, wherein the first bumps are located at a central region of the first active surface in linear arrangement and the first bumps are non-reflow bumps.

12. The flip-chip bonding method as claimed in claim 1, wherein the first bumps are pillar bumps, wherein each first bump has a solder cap disposed on a protruding surface of the first bump to solder to the corresponding connecting pad.

13. The flip-chip bonding method as claimed in claim 1, wherein the pressure oven has a gas entrance and an exhaust to make the gas inside the pressure oven become high-pressure fluid when the first underfill material is cured.

14. The flip-chip bonding method as claimed in claim 1, wherein the first bumps of the first chip are located at peripheries of the first active surface.
